(19) United States
(12) Patent Application Publication
(10) Pub. No.: US 2002/0185369 A1
(43) Pub. Date: Dec. 12, 2002

(54) Method of forming film by sputtering, optical member, and sputtering apparatus

(76) Inventor: Mitsuharu Sawamura, Kanagawa (JP)

Correspondence Address: FITZPATRICK CELLA HARPER & SCINTO, 30 ROCKEFELLER PLAZA, NEW YORK, NY, 10112, US

(21) Appl. No.: 10/157,972

(22) Filed: May 31, 2002

(30) Foreign Application Priority Data
Jun. 8, 2001 (JP) 174088/2001(PAT.)

(51) Int. Cl. C23C 14/32

(52) U.S. Cl. 204/192.12; 204/192.1; 148/518

(57) ABSTRACT

A minute multilayer film with good characteristics is automatically and continuously formed on an in-line basis at a low production cost. In a sputtering chamber, there is provided a bonded target in which a first Ti member, a first Si member, a second Ti member, a Ta member, and a second Si member are bonded and which acts as a cathode electrode. A power is supplied between a substrate and the bonded target, and a substrate and a substrate holder are moved. With the movement, the substrate successively comes to face the first Ti member, first Si member, second Ti member, Ta member, and second Si member of the bonded target and sputtering is carried out on the substrate. A multilayer thin film of a structure consisting of a TiO₂ film, an SiO₂ film, a TiO₂ film, a Ta₂O₅ film, and an SiO₂ film is formed on a surface of the substrate. The thickness of each layer is adjusted by a film thickness correcting plate interposed between the substrate and the bonded target.

### BACKGROUND OF THE INVENTION

1. Field of the Invention

The present invention relates to an optical member having a multilayer thin film as an antireflection film, used in optical instruments such as cameras, liquid crystal projectors, and so on, a method of forming a multilayer thin film, and a sputtering apparatus.

2. Related Background Art

In recent years, the sputtering process has come to be used as a method of forming an antireflection film provided in optical members for optical instruments.

Japanese Patent Publication No. 7-111482 describes an example of a five-layer antireflection film formed by a reactive DC sputtering system of an in-line type.

In order to mass-produce optical members of a large area by the sputtering process, it is preferable to use a sputtering system of the in-line type (constituting an automatic and continuous production line) suitable for continuous film formation under fixed conditions. Normally, the system configuration of the sputtering system, specifically, the number of sputtering chambers or the number of sputtering devices, is determined according to a target production amount and a target process time.

A plurality of targets are generally used in a process of forming a multilayer film or in a process using a target material with a low film-forming rate. For the process using the plurality of targets as described, the sputtering system is sometimes provided with a plurality of sputtering devices or a plurality of sputtering chambers. When the sputtering system is provided with a plurality of sputtering devices or a plurality of sputtering chambers corresponding to the respective targets, each sputtering device or each sputtering chamber needs to be equipped with a power source, and this increases the equipment cost. Even in the case where the plurality of targets are set in one sputtering chamber, it is necessary to prepare a plurality of power sources according to the number of targets, and this configuration also increases the equipment cost.

Japanese Patent Application Laid-Open No. 8-165575 describes a method of forming a multilayer film by a planar magnetron sputtering system wherein a target member mounted on an upper surface of a common cathode is segmented into two or more kinds of target materials in a conveying direction of a substrate, wherein a magnetic circuit of the cathode has at least one of a strength difference of a width difference in the conveying direction, and wherein a multilayer film is produced by application of a power from a sputtering power source connected to the cathode.

In the sputtering method described in Laid-Open No. 8-165575 above, an anode is used in order to prevent different kinds of sputtered particles flying from the respective target from mixing, which makes the structure of the system complicated. In addition, some of sputtered particles are not used for formation of a film, which results in lowering of the film-forming efficiency.

### SUMMARY OF THE INVENTION

It is, therefore, an object of the present invention to provide a sputtering apparatus and a film forming method using a sputtering device with less cathodes that can form a multilayer film at a low production cost with good film controllability by use of a simple structure.

According to an aspect of the present invention, there is provided a method of forming a multilayer thin film, comprising the steps of preparing a bonded target in which a plurality of members of different materials are bonded, wherein the materials and the widths thereof are determined according to refractive indices and film thicknesses necessary for respective layers of a multilayer thin film to be formed on a substrate; placing the bonded target in a sputtering chamber; and carrying the substrate into the sputtering chamber, moving the substrate at a speed according to the refractive indices and the film thicknesses necessary for the respective layers of the multilayer thin film to be formed on the substrate, and performing sputtering with the bonded target being used as a cathode electrode.

By this method, it is feasible to form a desired multilayer film by use of a single target, to reduce the equipment cost greatly, to form a film with satisfactory film characteristics, and to implement automatic and continuous processing of the in-line type.

It is also possible to modify the method so that a film thickness correcting plate is interposed between a part of the bonded target and a moving path of the substrate to adjust the thickness of a layer of the multilayer thin film to be formed using the member of the bonded target lying in the portion covered by the film thickness correcting plate. This permits formation of layers of different thicknesses from the same material while controlling the thicknesses as needed.

The multilayer thin film may include a region in which different materials are mixed, at a boundary between layers. In this case, the region is an index gradient portion where the refractive index varies, and desired film characteristics can be yielded by constructing this region in a given configuration.

Preferably, a power is supplied from a single power source to the bonded target. In this case, since the system is equipped with a single target and a single power source, the equipment cost is very low.

The bonded target may be comprised of a metal and Si and reactive DC sputtering may be performed using the bonded target as a cathode electrode. The metal can be selected from high-index materials such as Ti, Nb, Ta, Zr, and so on, and a low-index material such as Al. Further, Si is used as a low-index material.

The film forming method described above is suitable for formation of an antireflection film for optical members. The antireflection film is comprised of a multilayer thin film comprised of a plurality of layers with different refractive indices.

According to another aspect of the present invention, there is provided a sputtering apparatus comprising a sputtering chamber into which a plurality of substrates are continuously carried; a bonded target which is placed in the sputtering chamber and in which a plurality of members of different materials are bonded; and a mechanism for moving the plurality of substrates at a variable speed.

In order to form a multilayer thin film comprising a plurality of layers with different refractive indices on the substrates, the materials and the sizes of the plurality of members may be selected according to refractive indices and film thicknesses necessary for the respective layers of the multilayer thin film and the thus selected members may be bonded to one another to form the bonded target.

The apparatus may further comprise a film thickness correcting plate interposed between a part of the bonded target and a moving path of the substrate, and a single power source for supplying a power to the bonded target.

### BRIEF DESCRIPTION OF THE DRAWINGS

FIG. 1 is a schematic representation showing the sputtering apparatus of the present invention;

FIG. 2 is a time chart illustrating the sputtering method of the present invention;

FIG. 3 is an enlarged view showing a multilayer thin film formed in a first embodiment of the present invention;

FIG. 4 is a graphical representation showing the relationship between the film thickness and the refractive index of the multilayer thin film formed in the first embodiment of the present invention;

FIG. 5 is a graphical representation showing the relationship between the film thickness and the refractive index of the multilayer thin film formed in the first embodiment of the present invention and the relationship between the film thickness and the refractive index of a multilayer thin film formed in a second embodiment, in comparison with each other;

FIG. 6 is a graphical representation showing the antireflection characteristics of the multilayer thin film formed in the first embodiment of the present invention;

FIG. 7 is a graphical representation showing the film thickness distribution of the multilayer thin film formed in the first embodiment of the present invention;

FIG. 8 is an enlarged view showing the multilayer thin film formed in the second embodiment of the present invention;

FIG. 9 is a graphical representation showing the relationship between the film thickness and the refractive index of the multilayer thin film formed in the second embodiment of the present invention;

FIG. 10 is a graphical representation showing the antireflection characteristics of the multilayer thin film formed in the second embodiment of the present invention; and

FIG. 11 is a graphical representation showing the film thickness distributions of the multilayer thin film formed in the second embodiment of the present invention.

### DETAILED DESCRIPTION OF THE PREFERRED EMBODIMENTS

The embodiments of the present invention will be described below with reference to the drawings. It is, however, noted that the present invention is by no means intended to be limited to the embodiments.

(First Embodiment)

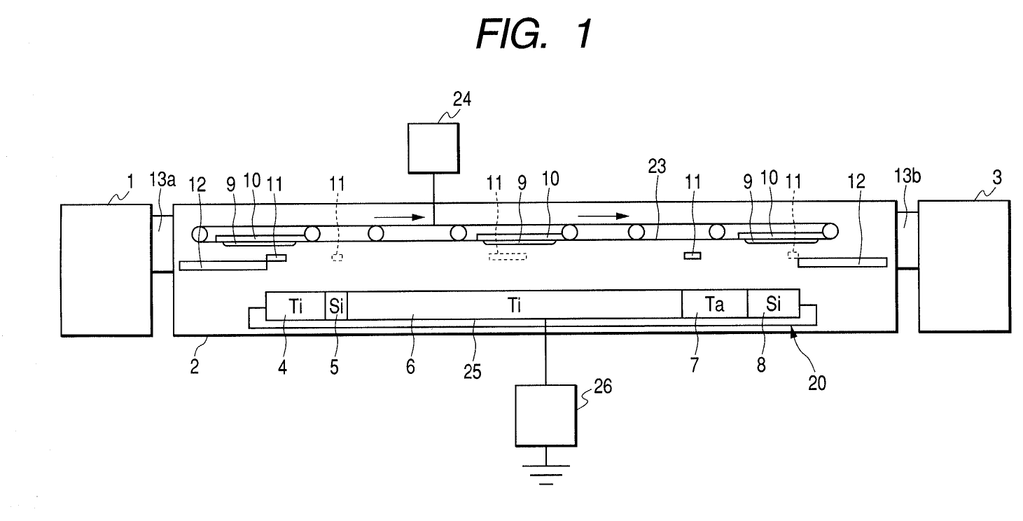

FIG. 1 schematically shows an in-line type sputtering apparatus in accordance with a first embodiment of the present invention. As shown in FIG. 1, this sputtering apparatus is comprised of a loading chamber 1, a sputtering chamber 2, and an unloading chamber 3, and is constructed so that an unprocessed substrate 9 is carried at a desired time from the loading chamber 1 into the sputtering chamber 2, film formation by sputtering is carried out in the sputtering chamber 2, and a processed substrate 9 is discharged into the unloading chamber 3.

A bonded target 20 acting as a cathode electrode is disposed in the sputtering chamber 2. The bonded target is of a configuration wherein a plurality of members of different materials are bonded to form an integral body. In the present embodiment the bonded target 20 consists of a first Ti member 4, a first Si member 5, a second Ti member 6, a Ta member 7, and a second Si member 8 bonded in the mentioned order, and extends over the most of the longitudinal length of the sputtering chamber 2.

The bonded target 20 is bonded to a backing plate 25.

A plurality of substrate holders 10 are arranged to hold respective substrates and to be conveyed in the direction of arrows by a conveying mechanism 23 consisting of a sprocket and a chain with supply of a driving force from a driving motor 24. The conveyance path of the substrate holders 10 is a moving path of the substrates. This conveying mechanism 23 is one capable of conveying the substrate holders 10 through the three chambers of the loading chamber 1, sputtering chamber 2, and unloading chamber 3 and moves the substrate holders 10 straight at a constant speed across gate valves 13a, 13b located at boundaries between chambers. The substrate holders 10 are subjected to continuous circulating motion of moving with a substrate 9 thereon in the direction of arrows and thereafter returning without any substrate 9 thereon to the loading chamber 1 (in the direction opposite to the arrows), though not detailed herein.

This sputtering apparatus is provided with an evacuation means (not shown) for the sputtering chamber 2 and an evacuation means (not shown) for both the loading chamber 1 and the unloading chamber 3. The present embodiment is configured so that the timing for evacuation from the loading chamber 1 is synchronized with that for evacuation from the unloading chamber 3. When the substrate holders 10 move into and out of the sputtering chamber 2, the loading chamber 1, the sputtering chamber 2, and the unloading chamber 3 are maintained at an identical pressure and, at the same time as a substrate holder 10 moves from the loading chamber 1 into the sputtering chamber 2, another substrate holder 10 moves from the sputtering chamber 2 into the unloading chamber 3.

The loading chamber 1, the sputtering chamber 2, and the unloading chamber 3 are provided each with a gas introducing means (not shown). There is also provided a power source 26 connected to the backing plate 25. The power source 26 is a DC power source in the present embodiment, but it can also be an AC power source.

Film thickness correcting plates 11 are located at desired positions according to a configuration of multilayer thin film 21 to be formed, between the moving path of the substrates 9, i.e., the conveying path of the substrate holders 10 and the bonded target 20. For convenience' sake, the film thickness correcting plates 11 used in the formation of the multilayer thin film used in the second embodiment described hereinafter are illustrated by dashed lines. In the vicinity of the ends of the bonded target 20 on the loading chamber 1 side and on the unloaded chamber 3 side, there are shielding plates 12 interposed between the bonded target 20 and the conveying path of the substrate holders 10.

Specifically, in the present embodiment, the apparatus is constructed in the structure such that the substrate holders 10 are circular and have a diameter of 150 mm and the bonded target 20 is of 1350 mm long×250 mm wide, in which the components are arranged such that the clearance between the substrates 9 mounted on the substrate holders 10, and the bonded target 20 becomes 80 mm. The substrate holders 10 are conveyed at a speed of 2.1 mm/sec.

The gas introducing means for each chamber includes two systems for introduction of Ar gas and for introduction of O₂ gas and controls the total pressure thereof while maintaining the flow rate ratio thereof constant. The power source 26 is a DC power source of 10 kW and is always kept in an on state during operation (during film-forming processing).

In this sputtering apparatus, sputtering was actually performed on substrates of borosilicate crown glass (BK7) in a disk shape with a diameter of 110 mm.

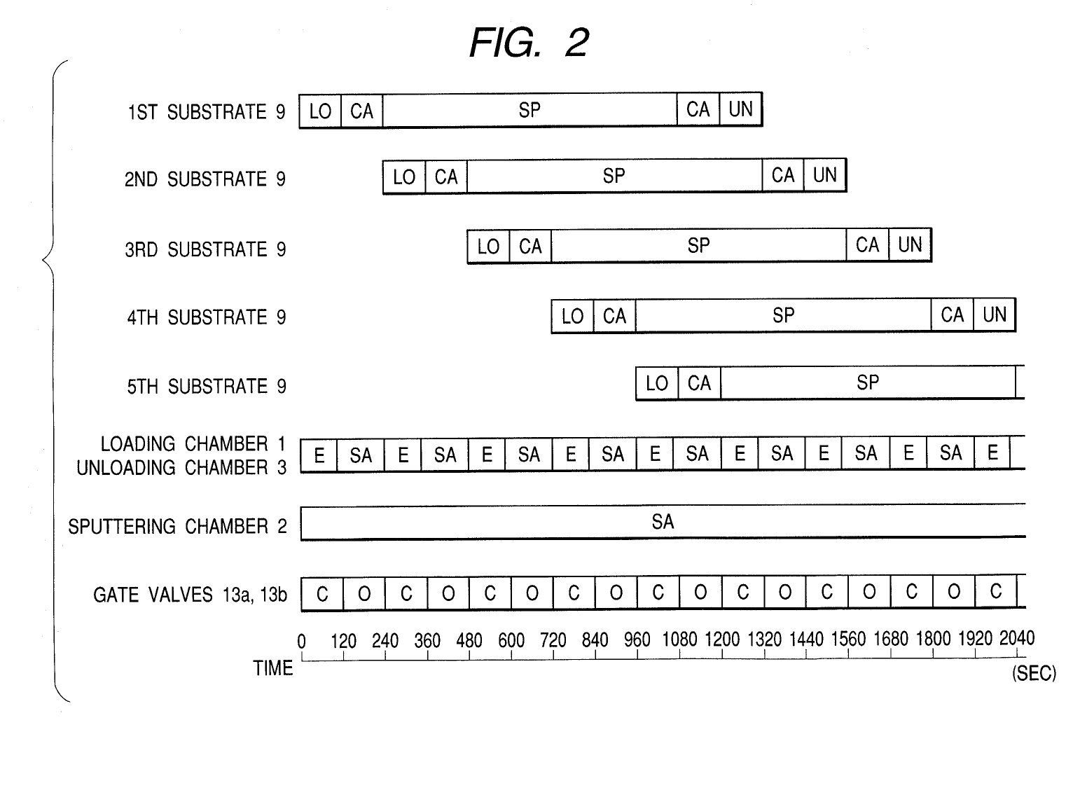

The sputtering steps will be described below in detail with reference to FIGS. 1 and 2. FIG. 2 is a time chart showing the sputtering method of the present invention. FIG. 2 shows the processing for five substrates 9 out of a number of substrates 9 to be continuously processed. In the present embodiment, because the evacuation and gas introduction operations are carried out at the same timing and in the same manner in the loading chamber 1 and in the unloading chamber 3, the operations for these chambers are illustrated in a common time chart. Since the gate valves 13a and 13b are opened and closed at the same timing and in the same manner, the opening and closing operations are illustrated in a common time chart. In the cells of the timing chart shown in FIG. 2, “LO” means “loading chamber”; “CA” means “carrying”; “SP” means “sputtering chamber”; “UN” means “unloading chamber”; “E” means “exposure to atmosphere”; “SA” means “sputtering atmosphere”; “C” means “close”; and “O” means “open”.

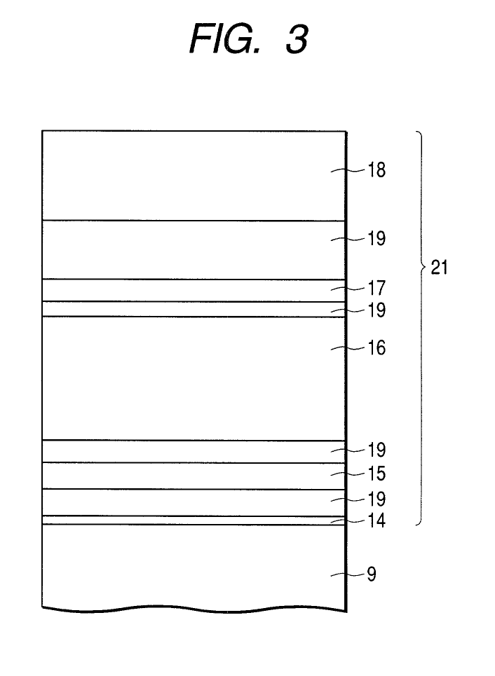

FIG. 3 is an enlarged view showing a multilayer thin film formed in the first embodiment of the present invention.

First, a substrate 9 is mounted on a substrate holder 10 to be set in the loading chamber 1, the loading chamber 1 is exposed to the atmosphere, and the interior of the loading chamber 1 is evacuated by the unrepresented evacuation means. Then, Ar gas and O₂ gas are introduced into each chamber 1, 2, 3 by the unrepresented gas introducing means. When at least the loading chamber 1 and the sputtering chamber 2 reach a constant condition of the pressure of 0.5 Pa and the partial pressure of O₂ of 20% (sputtering atmosphere), the gate valve 13a is opened and the substrate holder 10 with the substrate 9 thereon is carried from the loading chamber 1 into the sputtering chamber 2.

The substrate holder 10 is moved at a constant speed through the entire sputtering process.

In the sputtering chamber 2, a DC power of 8 kW from the power source 26 is supplied between the substrate 9 and the bonded target 20 to effect sputtering. Immediately after the entry into the sputtering chamber 2, the first Ti member 4 of the bonded target 20 comes to face the substrate. Therefore, sputtering is effected with the first Ti member 4 being used as a target, whereby a TiO₂ film (TiO₂-rich film) 14 is formed on the surface of the substrate 9, as shown in FIG. 3. A film thickness correcting plate 11 is placed between the moving path of the substrate 9 and the bonded target 20, so that the thickness of the film 14 formed is smaller than that in the case of omitting the film thickness correcting plate 11 by a thickness corresponding to the degree of shielding the substrate 9 from the bonded target 20 by means of the film thickness correcting plate 11.

While the power is continuously supplied from the power source 26 to between the substrate 9 and the bonded target 20, the substrate 9 and substrate holder 10 are moved in the direction of the arrows.

With the movement, the first Si member 5 comes to face the substrate 9, subsequently to the first Ti member 4. Then, sputtering is carried out with the first Si member 5 being used as a target, whereby an SiO₂ film (SiO₂-rich film) 15 is formed on the TiO₂ film 14 as shown in FIG. 3. This is substantially equal to an operation of first performing sputtering with a Ti target and, thereafter replacing the Ti target with an Si target and performing sputtering again with the Si target.

Thereafter, the substrate is moved similarly with supply of the power from the power source 26, whereby the second Ti member 6, the Ta member 7, and the second Si member 8 come to face the substrate 9, subsequently to the first Si member 4. Sputtering is sequentially carried out with each of these members being used as a target, whereby a TiO₂ film (TiO₂-rich film) 16, a Ta₂O₅ film (Ta₂O₅-rich film) 17, and an SiO₂ film (SiO₂-rich film) 18 are formed on the SiO₂ film 15. Thus, in the present embodiment, as shown in FIG. 3, the multilayer thin film 21 of the successively stacked configuration of the TiO₂ film 14, SiO₂ film 15, TiO₂ film 16, Ta₂O₅ film 17, and SiO₂ film 18 on the surface of the substrate 9; namely, an antireflection film having a refractive index varied in the thickness direction is formed.

The following will describe how to determine each of conditions for the sputtering.

The refractive indices and film thicknesses necessary for the respective films 14 to 18 and the boundary portions between layers are preliminarily determined by experiment or simulation on the basis of the required characteristics of the multilayer thin film.

The sputtering time is determined according to the required refractive index and film thickness necessary for each film. Then, determined are the conveying speed of the substrate holder 10 and the sputtering conditions including the sputtering pressure and others, the widths of the respective members 4 to 8 constituting the bonded target 20, and the location and width of each film thickness correcting plate 11 provided corresponding to one of the respective members 4 to 8. The term “width” used herein refer to the length in the conveying direction of the substrate holder 10.

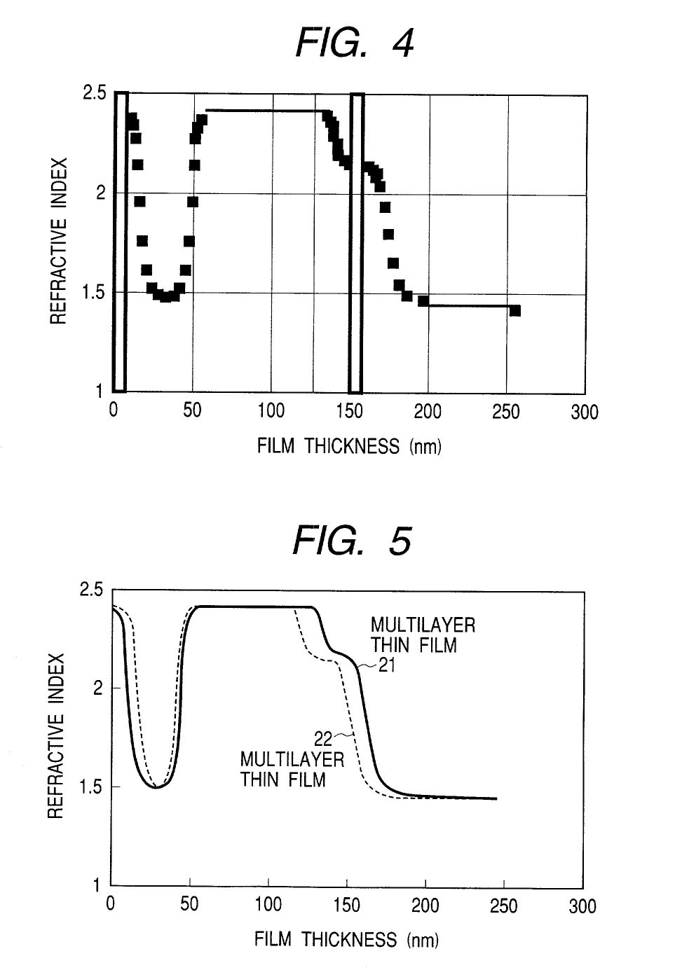

In the present sputtering method, since there is no shielding plate provided above the joints of the bonded target, regions 19, in which the materials of two adjacent members out of the members 4 to 8 constituting the bonded target 20 are mixed, are formed at the boundary portions between the films 14 to 18. Besides, the ratio of the materials of two adjacent members gradually varies in each region 19. Accordingly, the variation of refractive index is continuous between layers in the multilayer thin film 21 (see FIGS. 4 and 5).

The film formation method as described above can yield the antireflection characteristics equivalent to those of the conventional antireflection films, as described hereinafter, provided that the materials and widths of the respective members forming the bonded target and the conveying speed of the substrate are properly determined.

In this case, sputtered particles can be effectively utilized, because there is no shielding plate above the joints between the members of the bonded target.

After the multilayer thin film 21 is formed on the surface of the substrate 9 in the sputtering chamber 2 in this way, the gate valve 13b is opened and the substrate 9 and substrate holder 10 are carried from the sputtering chamber 2 into the unloading chamber 3. At this time, the interior of the unloading chamber 3 is maintained substantially in the same sputtering atmosphere as the interior of the sputtering chamber 2. Then, the gate valve 13b is closed, the unloading chamber 3 is exposed to the outside atmosphere, and then the substrate 9 is taken to the outside.

Although the processing of one substrate 9 has been described above with the elapse of time, in the present embodiment mass production is continuously carried out with consecutive feeding of substrates 9, as shown in FIG. 2, using the in-line type sputtering apparatus. Namely, on the way of processing of the substrate 9 as described above, processing of the subsequent substrate 9 is started. Specifically, after the first substrate 9 is carried from the loading chamber 1 into the sputtering chamber 2, the gate valve 13a is closed, the loading chamber 1 is exposed to the outside atmosphere, and the subsequent substrate 9 is carried into the loading chamber 1. In the operation thereafter, after a preceding substrate 9 is put into the sputtering chamber 2, a next substrate 9 is set in the loading chamber 1.

After the start of sputtering on the first substrate 9, sputtering is always carried out on any one substrate 9 in the sputtering chamber 2 during the operation of the sputtering apparatus, and thus the interior of the sputtering chamber 2 is always maintained in the sputtering atmosphere (the sputtering pressure of 0.5 Pa and the partial pressure of O₂ of 20%). In order to maintain this sputtering atmosphere, the loading chamber 1 is preliminarily brought into the same atmosphere as the sputtering atmosphere before the opening operation of the gate valve 13a in order to carry a new substrate 9 from the loading chamber 1 into the sputtering chamber 2, and the unloading chamber 3 is preliminarily brought into the same atmosphere as the sputtering atmosphere before the opening operation of the gate vale 13b in order to carry a processed substrate 9 from the sputtering chamber 2 into the unloading chamber 3. Namely, before opening the gate valve 13a or 13b, the loading chamber 1 or the unloading chamber 3 is preliminarily evacuated once by the evacuation means and thereafter the Ar gas and O₂ gas are introduced by an appropriate amount by the gas introducing means.

In the present embodiment, as shown in FIG. 2, the time necessary for all the steps of processing of one substrate 9 (from carrying-in to carrying-out of the substrate holder 10) is approximately twenty minutes and thirty seconds. However, since the subsequent substrate 9 is set in the loading chamber 1 whenever the preceding substrate 9 is put into the sputtering chamber 2 as described above, three or more substrates 9 are always processed in parallel in the sputtering chamber 2, and thus the processing time per substrate 9 is approximately five minutes. Therefore, the method of the present embodiment can achieve an extremely high efficiency.

The sputtering method of the present embodiment described above can implement the formation of the multilayer thin film 21 substantially similar to the sputtering process using a plurality of targets, specifically, five targets of a first Ti target, a first Si target, a second Ti target, a Ta target, and a second Si target, or at least three targets of a Ti target, an Si target, and a Ta target and using power sources in the same number as the number of the targets corresponding thereto.

FIG. 4 shows the relationship between the film thickness and the refractive index at the center of the substrate 9, of the antireflection film as the multilayer thin film 21 stacked on the substrate as described above. The vertical axis indicates the refractive index and the horizontal axis indicates the film thickness of the film formed by sputtering in the case where the film thickness correcting plates 11 are not provided. The regions encircled by the solid lines in FIG. 4 indicate those portions where no film is actually formed because of the shielding by the film thickness correcting plates 11, and the actual film thickness is thus smaller than that indicated on the horizontal axis of FIG. 4. The relationship between the actual film thickness and the refractive index of the antireflection film 21 (see FIG. 3) in the present embodiment is indicated by the solid line in FIG. 5. In the present embodiment, as illustrated, the thickness of each desired layer is smaller by an arbitrary amount by the use of the film thickness correcting plate 11. In this way, the antireflection film (multilayer thin film) 21 of the five-layer structure with the continuously varying index profile, which includes the TiO₂ layer 14, SiO₂ layer 15, TiO₂ layer 16, Ta₂O₅ layer 17, and SiO₂ layer 18 corresponding to the bonded target 20 and which has the mixture regions 19 at the boundaries between the layers, is formed on the substrate 9, as described above.

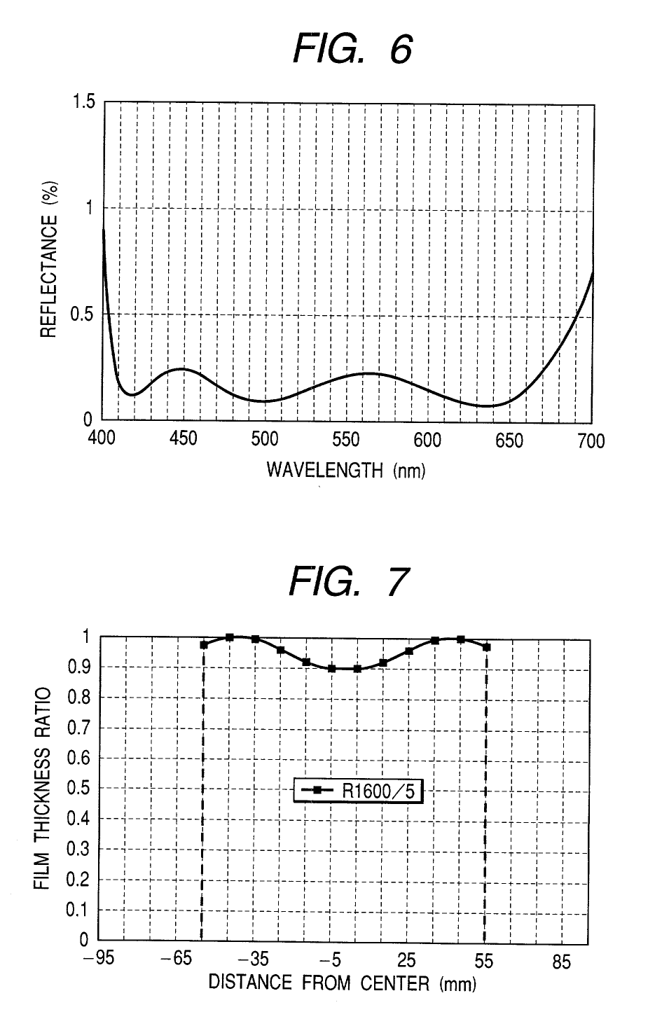

FIG. 6 shows the characteristics of the antireflection film 21. The vertical axis of FIG. 6 represents the reflectance (%) and the horizontal axis represents the wavelength (nm). The antireflection film 21 formed in the present embodiment is a continuous film including the mixture regions 19 of the different materials between the layers 14 to 18, different from the conventional antireflection films of five-layer structure of high-index and low-index films, but it can be provided with the antireflection characteristics equivalent to those of the conventional films.

FIG. 7 shows the film thickness distribution of the antireflection film 21. In the drawing, the horizontal axis represents the distance from the center of the substrate 9 and the vertical axis represents the film thickness ratio. In the drawing R1600 of “R1600/5” indicates the radius of curvature to define the convex shape of the surface of the substrate 9. In the present embodiment, because the radius of curvature is equal to 1600 mm, the substrate can be assumed substantially as a flat plate. The rest “/5” indicates that the thickness distribution in the direction normal to the conveying direction was measured at a position 5 mm apart in the conveying direction from the center of the film-forming surface. In the present embodiment, the effective film-forming range in the substrate holder 10 with the diameter of 150 mm is a range of +55 mm to −55 mm from the center, as indicated by the dashed lines. In this effective film-forming range, the film thickness distribution is within ±5%, and, where the conditions are set so as to yield the film thickness corresponding to the required antireflection characteristics at the positions of the distance ± about 25 mm, the error of the thickness is within the tolerance and within the range which is adjustable by an input power.

(Second Embodiment)

A second embodiment of the present invention will be described below. Description will be omitted as to the portions similar to those in the first embodiment.

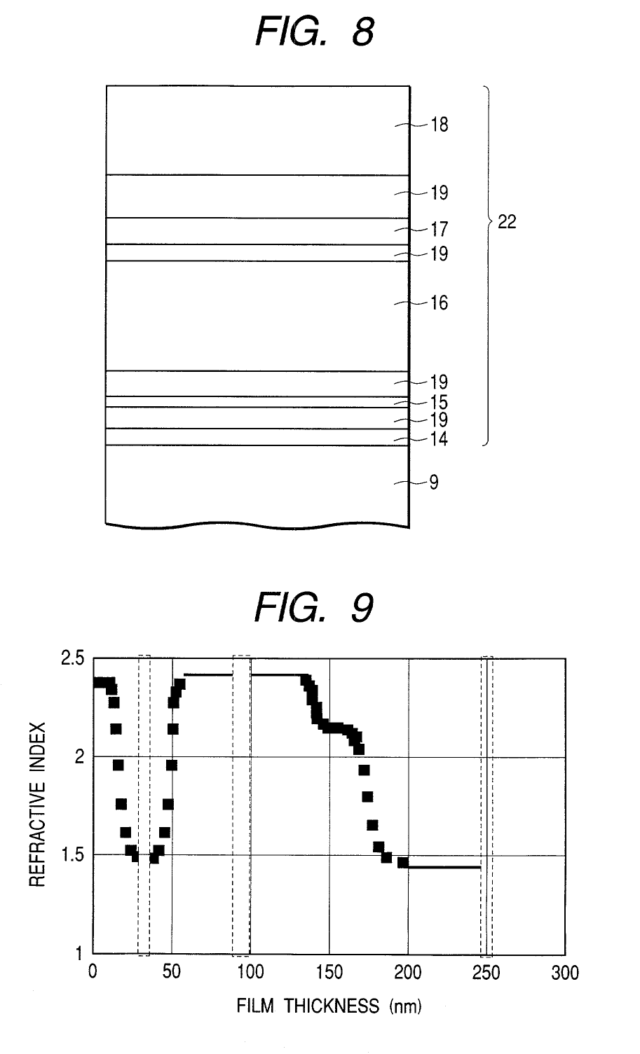

Using the sputtering apparatus shown in FIG. 1, an antireflection film 22 (see FIG. 8) as a multilayer thin film was formed on the surface of the substrate 9 made of LaSF03 and of a convex lens shape with a diameter of 110 mm and a radius of curvature of 200 mm.

FIG. 9 shows the relationship between the film thickness and the refractive index at the center of the substrate 9, of the antireflection film 22 stacked on the substrate 9 in the present embodiment. The vertical axis indicates the refractive index and the horizontal axis indicates the thickness of the film formed by sputtering in the case where the film thickness correcting plates 11 are not provided. The regions encircled by the dashed lines in the figure represent those portions where no film was actually formed because of the shielding by the film thickness correcting plates 11 (as indicated by the dashed lines in FIG. 1), and the actual thickness is smaller than that indicated on the horizontal axis in FIG. 9. The relationship between the actual thickness and the refractive index in the present embodiment is indicated by the dashed line in FIG. 5. In the present embodiment, as illustrated, the thickness of each desired layer is decreased by an arbitrary amount by the use of the film thickness correcting plate 11. In this way, the antireflection film 22 of the five-layer structure with the continuously varying index profile, which includes the TiO₂ layer 14, SiO₂ layer 15, TiO₂ layer 16, Ta₂O₅ layer 17, and SiO₂ layer 18 corresponding to the bonded target 20 and which has the mixture regions 19 at the boundaries between the layers, is formed on the substrate 9, as shown in FIG. 8. From the comparison between the solid line and the dashed line in FIG. 5 and the comparison between FIG. 3 and FIG. 8, it is seen that the multilayer thin film 21 formed in the first embodiment is different in the thicknesses of the respective layers from the multilayer thin film 22 formed in the second embodiment. This is because the first embodiment and the second embodiment are different from each other in the number, locations, and sizes of the film thickness correcting plates 11. In this way, the thicknesses of the respective layers can be arbitrarily increased or decreased by adjusting the number, locations, and sizes of the film thickness correcting plates 11.

FIG. 10 shows the characteristics of the antireflection film 22. In FIG. 10 the vertical axis represents the reflectance (%) and the horizontal axis represents the wavelength (nm). The antireflection film 22 formed in the present embodiment is a continuous film including the mixture regions 19 of the different materials between the layers, different from the conventional antireflection films of five-layer structure of high-index and low-index films, but it can be provided with the antireflection characteristics equivalent to those of the conventional films.

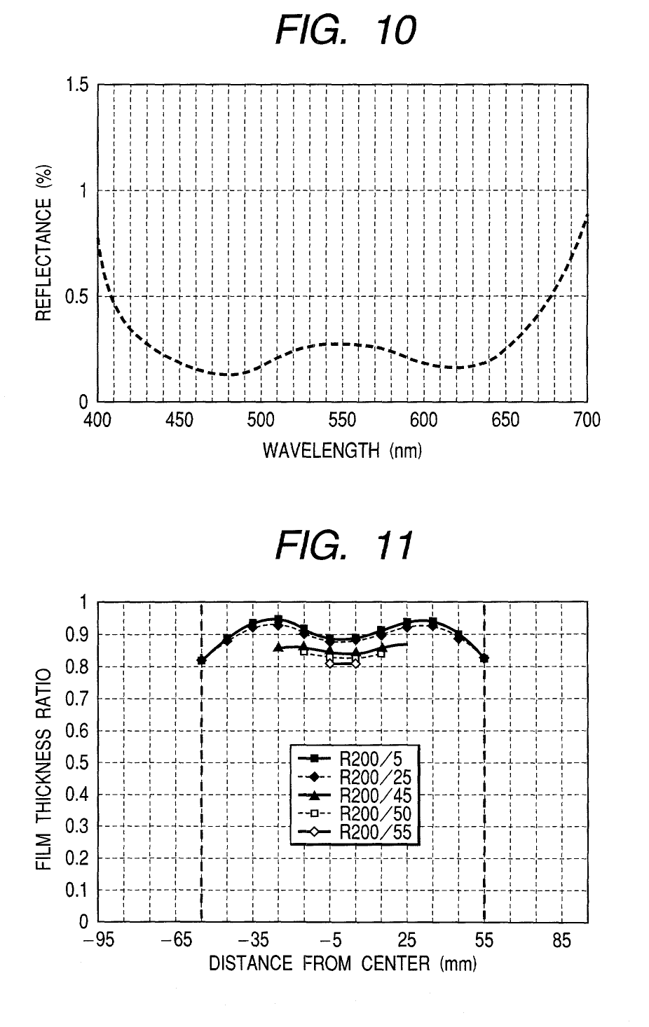

FIG. 11 shows the thickness distributions of the antireflection film 22. In the figure, the horizontal axis represents the distance from the center of the substrate and the vertical axis represents the film thickness ratio indicated on the basis of the same reference as in the case of the antireflection film 21 in the first embodiment shown in FIG. 7. In the figure, “R200/5” indicates that the substrate 9 was of a convex lens shape with a radius of curvature of 200 mm and that the film thickness distribution in the direction normal to the conveying direction was measured at the position 5 mm apart in the conveying direction from the center of the film-forming surface. Likewise, “R200/25” indicates that the film thickness distribution in the direction normal to the conveying direction was measured at the position 25 mm apart in the conveying direction from the center of the film-forming surface on the same substrate 9; “R200/45” indicates that the film thickness distribution in the direction normal to the conveying direction was measured at the position 45 mm apart in the conveying direction from the center of the film-forming surface on the same substrate 9; “R200/50” indicates that the film thickness distribution in the direction normal to the conveying direction was measured at the position 50 mm apart in the conveying direction from the center of the film-forming surface on the same substrate 9; “R200/55” indicates that the film thickness distribution in the direction normal to the conveying direction was measured at the position 55 mm apart in the conveying direction from the center of the film-forming surface on the same substrate 9. In the present embodiment, the minimum film thickness appeared at the region which was 55 mm apart from the center of the film formation area and was approximately 10% smaller than the thickness at the center. However, the film thickness distributions within the region of 50 mm from the center were within about ±5%, and they will raise no problem in practical use.

According to the present invention, by using a bonded target in which a plurality of members of different materials are bonded and by determining the materials and widths of the respective members constituting the bonded target, and the speed of movement of the substrate, according to the refractive indices and film thicknesses necessary for the respective layers in the multilayer thin film to be formed on the substrate, a desired multilayer thin film can be formed using a single target and a single power source.

Further, since there is not provided any shielding plate above the joints of the bonded target, a multilayer film with mixture layers of adjacent target members is formed, so that efficient film formation can be carried out.

In addition, the sputtering apparatus of the present invention can operate in the in-line type to implement automatic and continuous formation of a multilayer thin film on a substrate, and the thus formed multilayer thin film has satisfactory film characteristics. Accordingly, it is feasible to perform the in-line production readily at a low production cost even in small-scale production, to which it was hard heretofore to apply the in-line production because of a high production cost.

Further, the thickness of each layer of a multilayer thin film can also be arbitrarily adjusted more finely by interposing the film thickness correcting plate between a part of the bonded target and the moving path of the substrate.

What is claimed is:

1. A method of forming a multilayer thin film, comprising the steps of:
preparing a bonded target in which a plurality of members of different materials are bonded, wherein the materials and the widths thereof are determined according to refractive indices and film thicknesses necessary for respective layers of a multilayer thin film to be formed on a substrate;
placing the bonded target in a sputtering chamber; and
carrying the substrate into the sputtering chamber, moving the substrate at a speed according to the refractive indices and the film thicknesses necessary for the respective layers of the multilayer thin film to be formed on the substrate, and performing sputtering with the bonded target being used as a cathode electrode.

2. The method according to claim 1, further comprising the step of interposing a film thickness correcting plate between a portion of the bonded target and a moving path of the substrate to adjust the thickness of a layer of the multilayer thin film to be formed using the member of the bonded target lying in the portion covered by the film thickness correcting plate.

3. The method according to claim 1, further comprising the step of forming a region where the different materials are mixed, at a boundary between the layers of the multilayer thin film.

4. The method according to claim 1, wherein a power from a single power source is supplied to the bonded target.

5. The method according to claim 1, wherein the bonded target is comprised of a metal and Si and reactive DC sputtering is carried out with the bonded target as a cathode electrode.

6. An optical member comprising an antireflection film formed by the method as set forth in claim 1.

7. The optical member according to claim 6, wherein the antireflection film is a multilayer thin film comprising a plurality of layers with different refractive indices.

8. A sputtering apparatus comprising:
a sputtering chamber into which a plurality of substrates are continuously carried;
a bonded target which is placed in the sputtering chamber and in which a plurality of members of different materials are bonded; and
a mechanism for moving the plurality of substrates at a variable speed.

9. The sputtering apparatus according to claim 8, wherein, in order to form a multilayer thin film comprising a plurality of layers with different refractive indices on the substrates, the materials and the sizes of the plurality of members are selected according to refractive indices and film thicknesses necessary for the respective layers of the multilayer thin film and the thus selected members are bonded to one another to form the bonded target.

10. The sputtering apparatus according to claim 8, further comprising a film thickness correcting plate interposed between a portion of the bonded target and a moving path of the substrates.

11. The sputtering apparatus according to claim 8, further comprising a single power source for supplying a power to the bonded target.

12. The sputtering apparatus according to claim 8, wherein the bonded target is comprised of a metal and Si.
